(19) United States
(12) Patent Application Publication
(10) Pub. No.: US 2025/0204277 A1
(43) Pub. Date: Jun. 19, 2025

(54) SCALED SUPERCONDUCTING INTERPOSER FOR QUANTUM APPLICATIONS

(71) Applicant: INTERNATIONAL BUSINESS MACHINES CORPORATION, ARMONK, NY (US)

(72) Inventors: Michael Rizzolo, Delmar, NY (US); Hemanth Jagannathan, Niskayuna, NY (US)

(21) Appl. No.: 18/542,542

(22) Filed: Dec. 15, 2023

(51) Int. Cl. H10N 60/80; H10N 60/01; H10N 69/00

(52) U.S. Cl. CPC H10N 60/80; H10N 60/01; H10N 69/00

(57) ABSTRACT

A superconducting circuit includes a first metal layer, a first dielectric layer over the first metal layer, a second metal layer over the first dielectric layer, a second dielectric layer over the second metal layer, and a second metal layer over the second dielectric layer. The first and second dielectric layers include a low-k dielectric material.

### BACKGROUND

### Technical Field

The present disclosure generally relates to quantum chips and, more particularly, to quantum chips with thin metal-dielectric structures and methods of creation thereof.

### Description of the Related Art

Quantum chips exploit the principles of superposition and entanglement to perform complex computations and cryptographic operations beyond classical computers' capabilities. Quantum chips typically include quantum bits (qubits) as their fundamental information units. Qubits exist in a coherent superposition of states, enabling them to represent multiple values simultaneously. This unique property enables quantum chips to perform parallel computations, potentially leading to significant advancements in various fields such as optimization, simulation, and cryptography.

### SUMMARY

According to an embodiment, a superconducting circuit includes a first metal layer, a first dielectric layer over the first metal layer, a second metal layer over the first dielectric layer, a second dielectric layer over the second metal layer, and a third metal layer over the second dielectric layer. The first and second dielectric layers include a low-k dielectric material.

In some embodiments, which can be combined with the previous embodiment, the first, second, and third metal layers include different metals.

In some embodiments, which can be combined with one or more previous embodiments, the first, second, and third metal layers include the same metal.

In some embodiments, which can be combined with one or more previous embodiments, the first, second, and third metal layers have a thickness of about 20 nanometers to 150 nanometers, and the first and second dielectric layers have a thickness of about 40 nanometers to 300 nanometers.

In some embodiments, which can be combined with one or more previous embodiments, at least one of the first and second dielectric layers includes Silicon carbon nitride (SiCN).

According to another embodiment, a superconducting circuit includes a first metal layer, a first oxide layer over the first metal layer, a first dielectric layer over the first oxide layer, a second metal layer over the first oxide layer, a second oxide layer over the second metal layer, a second dielectric layer over the second oxide layer, and a third metal layer over the second dielectric layer.

In some embodiments, which can be combined with the previous embodiment, the first, second and third metal layers include different metals.

In some embodiments, which can be combined with one or more previous embodiments, the first, second, and third metal layers include a same metal.

In some embodiments, which can be combined with one or more previous embodiments, the first, second, and third metal layers have a thickness of about 20 nanometers to 150 nanometers.

In some embodiments, which can be combined with one or more previous embodiments the first and second dielectric layers have a thickness of about 40 nanometers to 300 nanometers.

In some embodiments, which can be combined with one or more previous embodiments, at least one of the first and second dielectric layers includes SiCN.

In some embodiments, which can be combined with one or more previous embodiments, the first and second dielectric layers include a low-k dielectric material.

In some embodiments, which can be combined with one or more previous embodiments, the first and second oxide layers include the same material.

In some embodiments, which can be combined with one or more previous embodiments, the oxide layer includes silicon oxide.

According to yet another embodiment, a method for forming a superconducting circuit includes forming a first metal layer, forming a first dielectric layer over the first metal layer, forming a second metal layer over the first dielectric layer, forming a second dielectric layer over the second metal layer, and forming a third metal layer over the second dielectric layer. The first and second dielectric layers include a low-k dielectric material.

In some embodiments, which can be combined with the previous embodiment, the first, second, and third metal layers include the same metal.

In some embodiments, which can be combined with one or more previous embodiments, the first, second, and third metal layers include different metals.

In some embodiments, which can be combined with one or more previous embodiments, the first, second, and third metal layers have a thickness of about 20 nanometers to 150 nanometers.

In some embodiments, which can be combined with one or more previous embodiments, the first and second dielectric layers have a thickness of about 40 nanometers to 300 nanometers.

In some embodiments, which can be combined with one or more previous embodiments, forming at least one of the first, second, and third metal layers is performed by an atomic layer deposition (ALD) technique or a Chemical Vapor Deposition (CVD) technique.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a superconductor circuit, in accordance with some embodiments.

FIG. 2 illustrates a superconductor circuit, in accordance with some embodiments.

FIGS. 3A-3B illustrate a superconductor circuit, in accordance with some embodiments.

FIG. 4 illustrates an electron microscopic view of the surface of a conventional semiconductor circuit, in accordance with some embodiments.

FIGS. 5A-5H illustrate stages in the fabrication of the superconductor circuit, in accordance with some embodiments.

FIG. 6 illustrates a block diagram of a method for forming the superconductor circuit, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the interconnect in use or operation in addition to the orientation depicted in the figures. For example, if the interconnect in the figures is turned over, elements described as “below” or “beneath” other elements or features would then be oriented “above” the other elements or features. Thus, for example, the term “below” can encompass both an orientation that is above, as well as, below. The interconnect may be otherwise oriented (rotated 90 degrees or viewed or referenced at other orientations) and the spatially relative descriptors used herein should be interpreted accordingly.

As used herein, the terms “lateral” and “horizontal” describe an orientation parallel to the first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a circuit and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

Quantum chips are advanced integrated circuits designed to harness the principles of quantum mechanics for computation, information processing, and other quantum-related tasks. Unlike classical bits, which represent information as either 0 or 1, quantum chips use quantum bits or qubits that can exist in a superposition of both states simultaneously. This unique property allows quantum chips to perform parallel computations, potentially solving complex problems more efficiently than classical computers.

Quantum chips typically consist of various components, including qubits, control electronics, readout devices, and interconnects. Qubits are the heart of quantum chips and can be realized using different physical systems such as superconducting circuits, trapped ions, or topological qubits. Control electronics manage the manipulation and interactions of qubits, while readout devices measure the quantum states of qubits to obtain useful information.

The metal-dielectric structure in quantum chips is used to control the flow of electrons between the qubits. The metal provides a pathway for electrons to flow, while the dielectric insulates the qubits from each other. Such a structure is essential for maintaining the delicate quantum states of the qubits. Wafer bow is a problem that can occur in quantum hardware processing, and can be caused by different layers (e.g., dielectric layers, metal layers, etc.) that have different stress states, different thermal expansion coefficients, etc. The wafer bow can cause chucking/tooling issues mid-processing.

There are a number of ways to mitigate wafer bows, such as using a special substrate that is less susceptible to warping. However, obtaining uniform control and using a specialized substrate can be expensive and hard to achieve.

To tackle the above-mentioned problems, disclosed is a superconductor circuit with improved sidewall coverage which features a thinned metal-dielectric structure. To that end, the disclosed superconductor circuit can offer thinner metal layers deposited without risking poor contact on via sidewalls. Further, the disclosed superconductor circuit can maintain interlevel capacitance, by lowering the dielectric constant while bringing the wires vertically closer together.

Accordingly, the teachings herein provide methods and systems of superconductor interconnect formation with thinned metal-dielectric structures. The techniques described herein may be implemented in a number of ways. Example implementations are provided below with reference to the following figures.

### Example Superconductor Circuit Structure

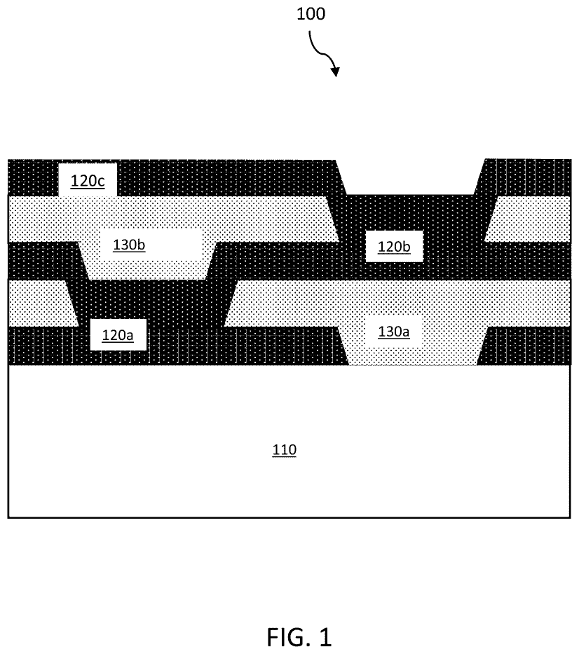

Reference now is made to FIGS. 1, which is a simplified cross-section view of a superconductor circuit 100, consistent with an illustrative embodiment. In various embodiments, the superconductor circuit 100 can include one or more dielectric layers to provide electrical insulation, reduce interference, and enhance qubit coherence. The superconductor circuit 100 can be engineered using dielectric materials with specific properties such as low loss, high dielectric strength, and minimal surface defects. The superconductor circuit 100 can include a substrate 110, a first metal layer 120a, a first dielectric layer 130a over the first metal layer 120a, a second metal layer 120b over the first dielectric layer 130a, a second dielectric layer 130b over the second metal layer 120b, and a third metal layer 120c over the second dielectric layer 130b.

Conventional superconductor circuits include an oxide layer between metal layers. In order to compensate for poor sidewall coverage, thick layers of metal, typically between 100 nanometers to 200 nanometers, and thick oxide layers, typically about 300 nanometers, may be deposited. Nevertheless, the stress caused by the thick films of metal can cause chucking issues, i.e., can cause a high wafer bow. Wafer bow, also known as wafer warpage, is a common issue encountered during the processing of superconductor circuits. Wafer bow refers to the non-uniform curvature of a wafer's surface, which can result from stresses induced during fabrication processes such as deposition, etching, and annealing. A wafer bow can cause misalignment between different layers of the superconductor circuit, affecting the precise placement of qubits, control elements, and interconnects. This misalignment can lead to decreased device performance and reliability of the superconductor circuit. Further, an uneven bow across a wafer can result in variations in the physical properties of qubits. This inhomogeneity can negatively impact qubit performance, coherence times, and reproducibility. Wafer bows can also disrupt the uniformity of interconnects and signaling pathways, leading to impedance mismatches and unwanted signal reflections. This can, in turn, degrade the quality of control and measurement signals. Additionally, wafer bows can lead to higher failure rates during the manufacturing process. It can result in defects, cracks, or poor adhesion between layers, reducing the overall yield of functional superconductor devices.

The wafer bow can cause even further disadvantageous in the case of multilevel wiring in superconductor devices. Multilevel wiring is a rather sophisticated architecture employed in quantum chips to manage and facilitate the complex interconnection of various components, such as qubits, control elements, and readout devices. This architecture involves multiple layers of conductive paths (wires) stacked on top of each other, allowing for efficient signal distribution, control, and measurement within the chip. By utilizing multiple layers, multilevel wiring can optimize space utilization within the limited footprint of the superconductor circuit 100, allow for the separation of different signal types, and prevent interference between control signals, readout signals, and qubit states to enhance the overall coherence and fidelity of qubits' quantum states.

The multilevel wiring architecture in the disclosed superconductor circuit 100 can include alternating layers of dielectric materials, i.e., the first and second dielectric layers 130a and 130b, and conductive metals, i.e., the first, second, and third metal layers, 120a, 120b, and 120c. Utilizing the first and second dielectric layers 130a and 130b in the superconductor circuit 100, instead of oxide layers in conventional superconductors, can provide a systematic framework for distributing control signals, synchronization pulses, and measurement signals to different components of the superconductor circuit 100, and can facilitate orchestrating the precise operations required for qubit manipulation and measurement in the superconductor circuit 100. Additionally, since the qubits in the superconductor circuit 100 can involve specific control signals, such as microwave pulses, to perform quantum gate operations, using the first and second dielectric layers 130a and 130b in the multilevel wiring architecture of the superconductor circuit 100 can enable the delivery of such signals to the appropriate qubits, allowing for precise and targeted manipulation of their quantum states.

Typically, the multilevel wiring structure of the superconductor circuits involves advanced fabrication techniques such as lithography and deposition. As the number of layers increases, the fabrication process becomes more complex, potentially leading to challenges in maintaining precise alignment and uniformity. As a result, conventional superconductor circuits require dielectric layers and metal layers with thicknesses of several hundred nanometers. However, unlike conventional superconductor circuits, the superconductor circuit 100 can include dielectric layers, i.e., the first and second dielectric layers 130a and 130b, with a thickness of about 20 nanometers to 150 nanometers or less. Replacing the thick oxide layers of conventional circuits with 20-nanometer to 150-nanometer thick first and second dielectric layers 130a and 130b can result in a more compact superconductor circuit 100 with preserved interlevel capacitance. The first and second dielectric layers 130a and 130b can be made of low-k dielectric materials. In some embodiments, the first and second dielectric layers 130a and 130b can be made of SiCN, BDIII, Gen2, and SiCOH.

The first metal layer 120a, the second metal layer 120b, and the third metal layer enable the distribution of electromagnetic signals across the superconductor circuit 100. The metals used in the first metal layer 120a, the second metal layer 120b, and the third metal layer 120c can be superconducting materials or highly conductive metals that allow for efficient transmission of signals. In some embodiments, one or more of the first metal layer 120a, the second metal layer 120b, and the third metal layer 120c can include Nb, NbN, NbAl, In, TiN, Ru, Al, Ti, or Ta. The MTL 120a, MTL 120b, and MTL 120c metal layers can serve as efficient pathways for transmitting control signals, microwave pulses, and measurement data to and from qubits and other quantum components. The low resistance of these pathways minimizes signal loss and ensures accurate and rapid control of qubit operations. In some embodiments, the via (not shown) can be formed within the metal layers, i.e., the first metal layer 120a, the second metal layer 120b, and the third metal layer 120c. In this way, an electrical connection between the different components is established, and efficient power delivery and signal transmission between the superconductor circuit 100 is facilitated.

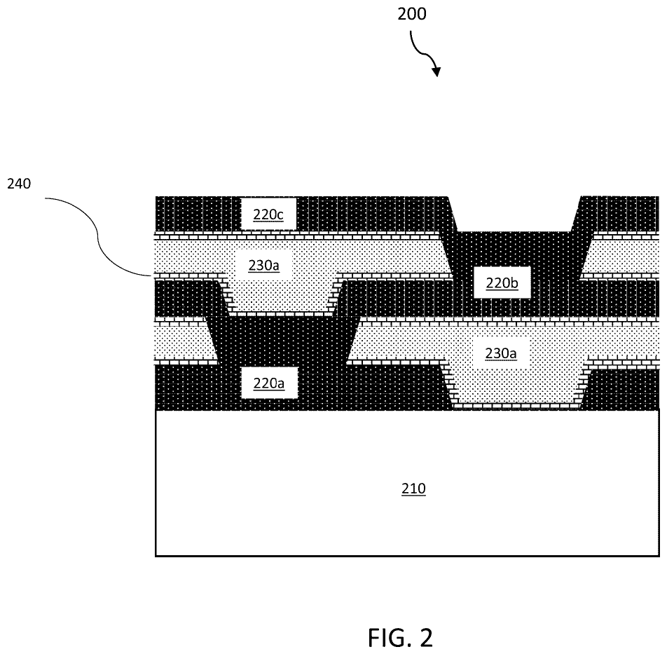

FIG. 2 illustrates a superconductor circuit 200 according to another aspect of the present disclosure. In some embodiments, the superconductor circuit 200 can include a thin layer of oxide formed between adjacent dielectric layers and metal layers, e.g., an oxide layer 240 between the second metal layer 220b and the first dielectric layer 230a. Utilizing the oxide layer ensures the same interface as the metal layer. In some embodiments, the oxide layer has a thickness of about 10-50 nanometers. Further, the oxide layer can be formed on via sidewalls.

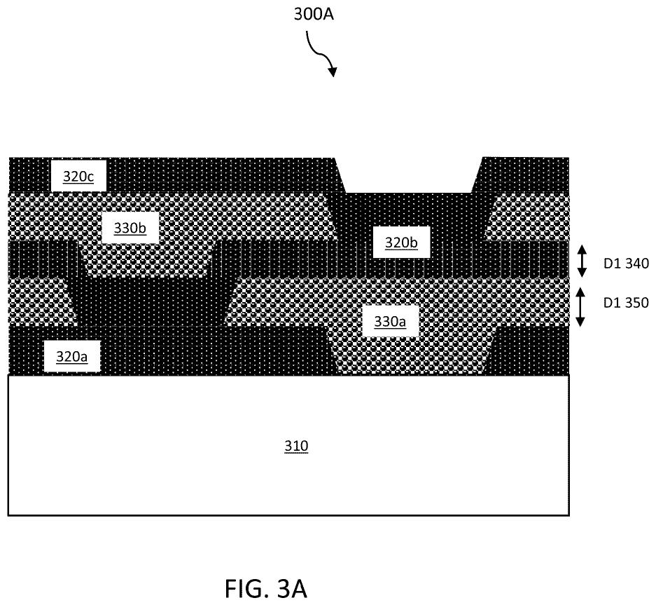

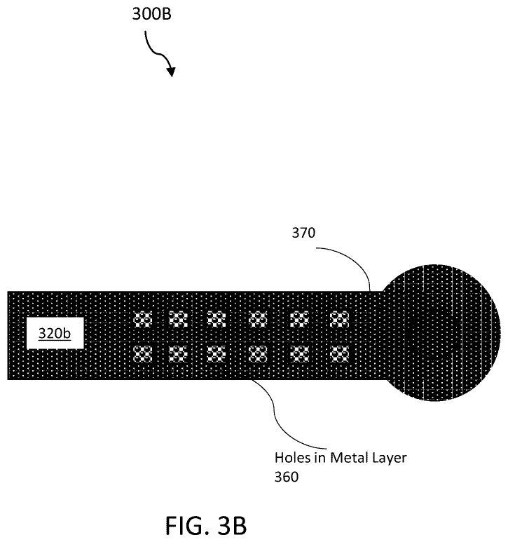

FIGS. 3A-3B illustrate a superconductor circuit 300A/B according to another aspect of the present disclosure. Referring to FIG. 3A now, in some embodiments, the superconductor circuit 300A can include thin layers of oxide layers and metal layers. That is, the superconductor circuit 300A can include metal layers, e.g., the first metal layer 230a, the second metal layer 230b, and the third metal layer 230c, with a thickness, D1 340, of less than 100 nanometers, and oxide layers, e.g., oxide 330a and oxide 330b, with a thickness, D2 350, of about 150 nanometers. Unlike conventional semiconductor circuits in which reducing the thickness of the metal and/or oxide layers can degrade resistance due to scattering or less conductive volume, the superconductor circuit's performance will not be adversely affected due to the lack of resistance issues in the case of superconductor circuits.

FIG. 3B illustrates a top view of the superconductor circuit 300B with the holes 360 (cheesed holes due to thinner oxide layers) on the second metal layer 320b and the location of the via 370 passing through the second metal layer 320b. In order to fabricate the superconductor 300B, conventional PVD can be used to deposit layers of metal followed by patterning metals within line cheesing to reduce the interlevel capacitance.

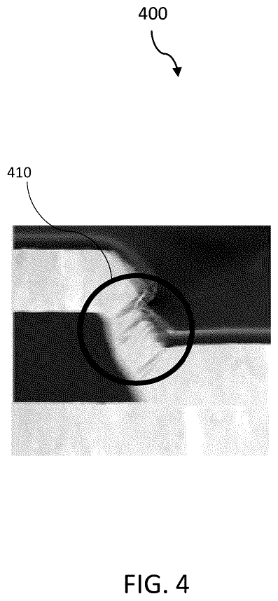

FIG. 4 illustrates the conventional superconductor circuit. As mentioned earlier, conventional superconductor circuits include thick alternating layers of metals and oxides. FIG. 4 depicts an issue 410 with the surface topography coverage of a conventional semiconductor circuit. Such a conventional semiconductor circuit requires depositing thick metal films, which in turn causes wafer bow issues.

### Example Processes for Superconductor Circuit Structures

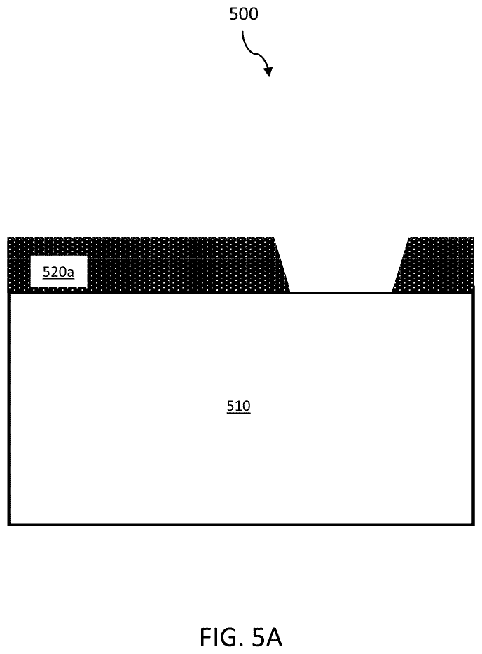

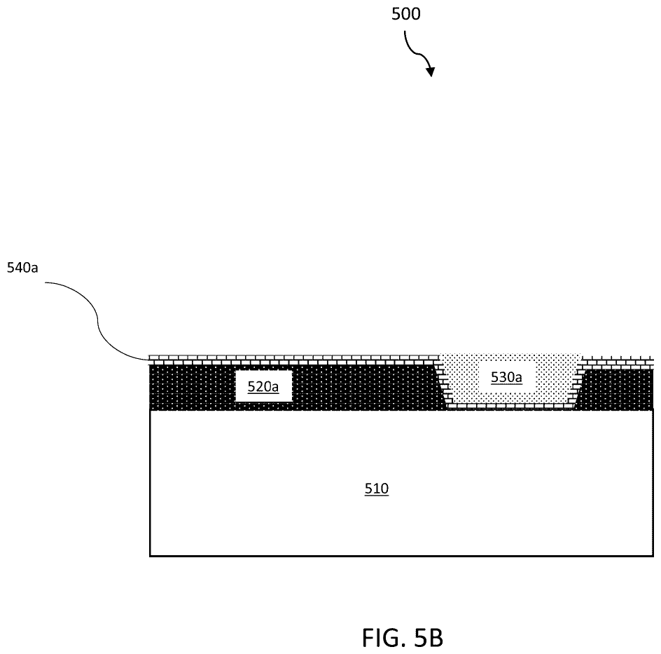

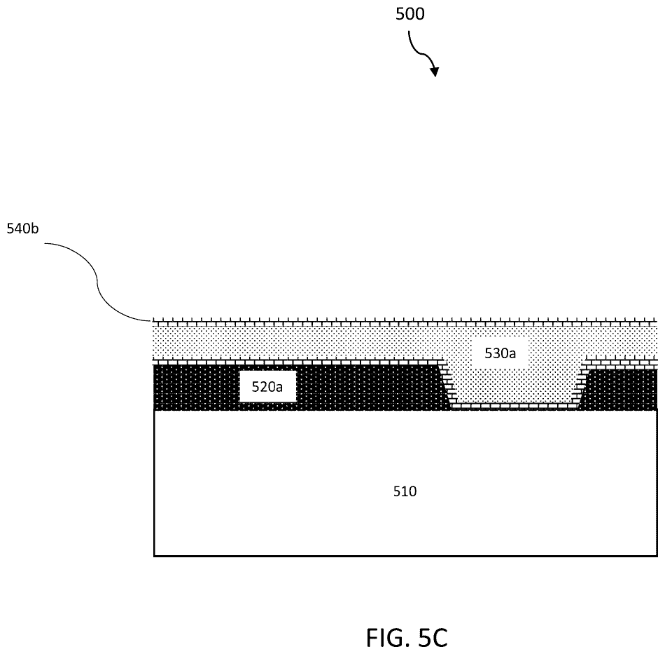

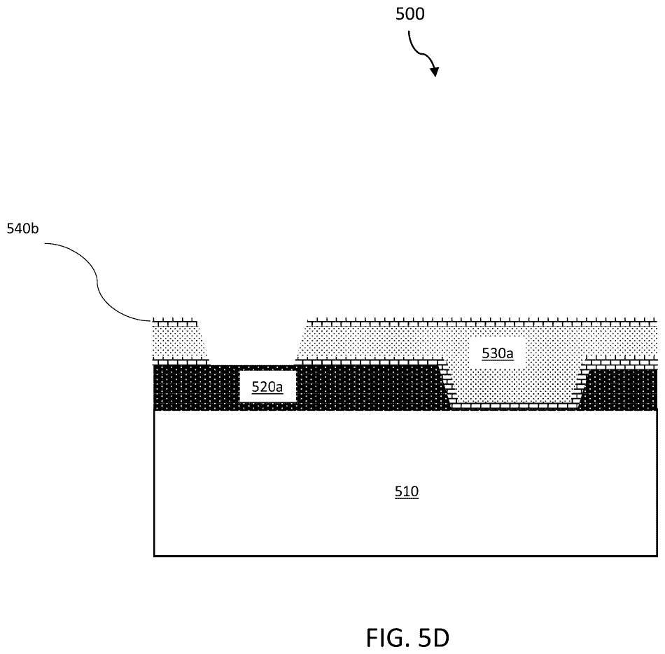

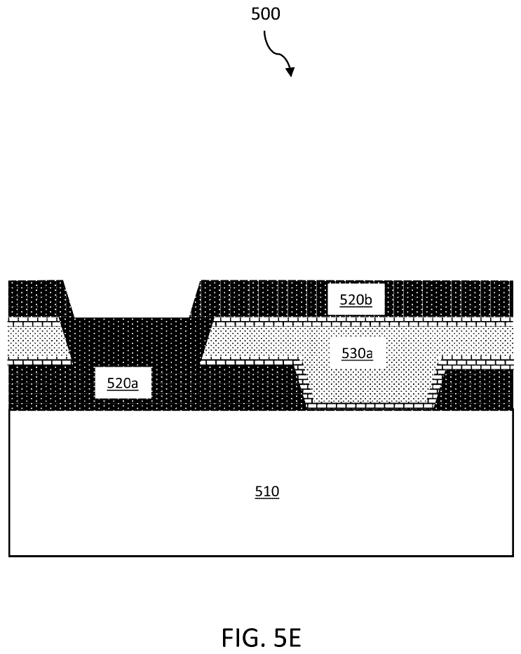

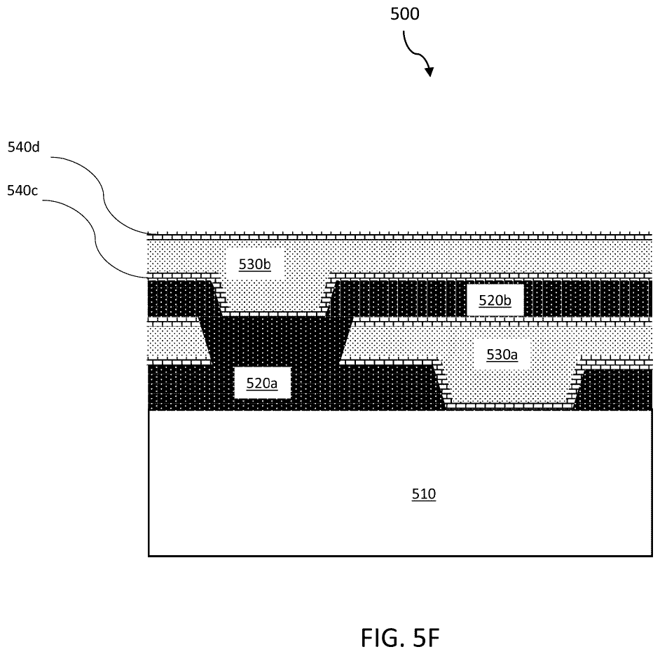

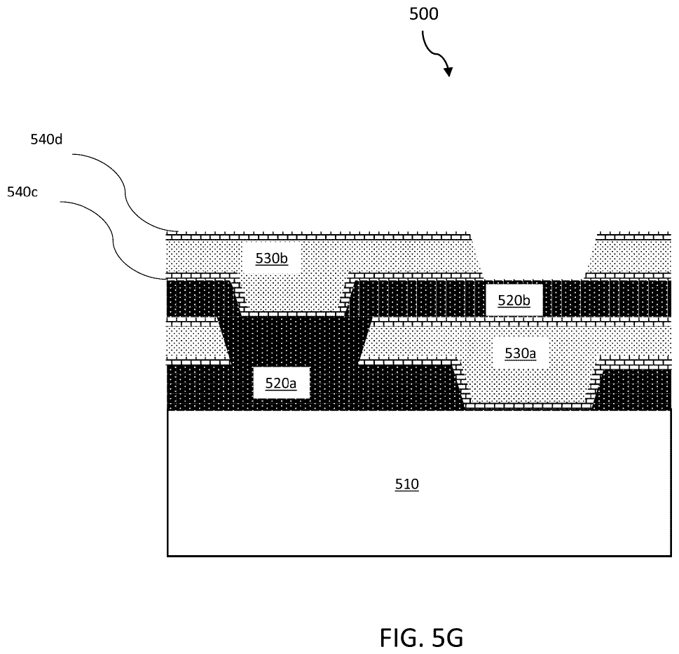

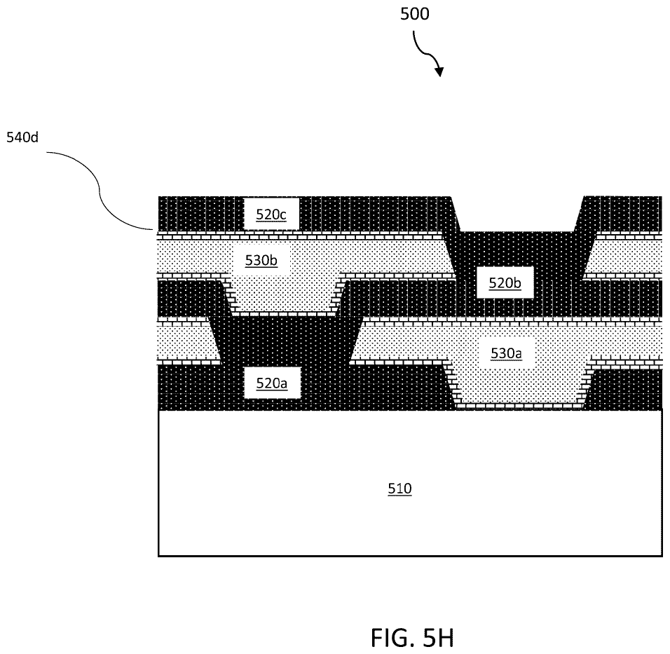

With the foregoing description of an example superconductor circuit 500, it may be helpful to discuss an example process of manufacturing the same. To that end, FIGS. 5A-5H illustrate various steps in manufacturing a superconductor circuit 100, consistent with illustrative embodiments.

For the sake of brevity, conventional techniques related to semiconductor circuit and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor circuits and semiconductor-based ICs are well known and so, in the interest of brevity, many conventional steps will only be mentioned briefly herein or will be omitted entirely without providing the well-known process details.

Fabrication of devices discussed herein can comprise multi-step sequences of, for example, photolithographic and/or chemical processing steps that facilitate the gradual creation of electronic-based systems, devices, components, and/or circuits in a semiconducting and/or a superconducting device (e.g., an integrated circuit). For instance, superconductor circuits 500A to 500H can be fabricated on one or more substrates (e.g., a sapphire, silicon (Si), SiOx, SiN, SiC substrate, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), back-grinding techniques, and/or another technique for fabricating an integrated circuit.

Referring to FIG. 5A now, a superconductor circuit 500A is shown after the formation of the first metal layer (deposition and patterning). In some embodiments, the first metal layer 520a can be deposited over a substrate 510. In the illustrative example depicted in FIG. 5, the superconductor circuit 500A is depicted as being on a substrate 510, while it will be understood that many types as substrates may be used, including, without limitation, sapphire, Si, SiOx, SiC, SiN, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 510 may include any suitable material or combination of materials, such as sapphire, doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In some embodiments, prior to forming the first metal layer 520a the substrate 510 is prepared by cleaning and removing any impurities or oxide layers. The first metal layer 520a is deposited onto the substrate 510 using techniques such as physical vapor deposition (PVD), chemical vapor deposition (CVD) or atomic layer deposition (ALD).

In an embodiment, in order to deposit the first metal layer 520a using ALD, which is a chemically controlled process that involves alternating pulses of precursor gases to form atomic layers one by one, and occurs in a vacuum chamber where the substrate is exposed to each precursor gas separately, the substrate 510 is exposed to the first precursor gas, which chemisorbs onto the substrate's surface, forming a monolayer of the desired material. The excess precursor is removed by purging the chamber with an inert gas, ensuring that only the chemisorbed molecules remain on the surface. Subsequently, substrate 510 can be exposed to the second precursor gas, which reacts with the chemisorbed layer to form a new layer of the desired material. Again, the excess precursor is purged from the chamber, leaving only the reacted layer behind. The process can be repeated for the desired number of cycles to build up the thin film layer by layer.

Alternatively, in some embodiments, in order to deposit the first metal layer 520a using CVD, which is a thin film deposition technique used to produce thin films on substrates through chemical reactions in a gaseous environment, the precursor gases containing the desired materials are introduced into the deposition chamber and then undergo chemical reactions on the substrate's surface, leading to the deposition of thin films. This can involve thermal decomposition or reaction with other species on the surface. As the reactions continue, the thin film layer grows in thickness on the substrate's surface.

In some embodiments, the first metal layer 520a can be deposited using a Physical Vapor Deposition (PVD) technique. PVD can form the first metal layer 520a over substrate 510 through physical processes without involving chemical reactions. To that end, the source material, i.e., the metal, is vaporized through evaporation, sputtering, or arc vaporization. The vaporized metal travels in a vacuum environment to the substrate 510, where it will be deposited. Upon reaching the substrate's surface, the vaporized metal condenses and forms a thin film. The film grows by accumulating atoms or molecules on the substrate 510. The deposited atoms or molecules may initially form small clusters or nuclei on the substrate. As deposition continues, these nuclei grow and coalesce to form a continuous thin film, i.e., the first metal layer 520a. In some embodiments, the PVD-grown first metal layer 520a ensures high quality of field region interface. In an embodiment, once the PVD is performed, a sidewall sealing step is performed by short-interval in-situ deposition of the metal utilizing either CVD or ALD. It should be noted that, upon deposition of each dielectric layer, a planarizing step is performed on the dielectric layer. Similarly, a person skilled in the art can understand the conventional steps required for patterning the vias.

FIG. 5B illustrates a superconductor circuit 500B after depositing the first dielectric layer. In some embodiments, the first dielectric layer 530a is deposited over portions of the first metal layer 520a. To that end, portions of the first metal layer 520a are removed, i.e., the first metal layer 520a is recessed. In some embodiments, in order to preserve the metal-oxide interface quality, Tetraethyl Orthosilicate, TEOS 540a, can be deposited over the first metal layer 520a. TEOS 540a can form over the first metal layer 520a, including the recessed portions of the first metal layer 520a. The first dielectric layer 530a subsequently fills the recessed portions of the first metal layer 520a. The first dielectric layer 530a can be deposited using CVD. In some embodiments, the first dielectric layer 530a has a thickness of about 100 nanometers to about 200 nanometers. In an embodiment, the first dielectric layer 530a has a thickness of about 150 nanometers. Chemical mechanical processing (CMP) can be performed to polish the surface of the first dielectric layer 530a and the TEOS 540a.

FIG. 5C illustrates a superconductor circuit 500C after depositing the first oxide layer. In some embodiments, once the first dielectric layer 530a fills the recessed portions of the first metal layer 520a, an additional layer of first dielectric layer 530a is deposited over the TEOS 540a, and the dielectric-filled recessed portions of the first metal layer 520a. In some embodiments, a first layer of oxide 540b is formed over the first dielectric layer 530a.

FIG. 5D illustrates a superconductor circuit 500D after recessing portions of the oxide layer and the dielectric layer. In some embodiments, portions of the first oxide layer 540b and the first dielectric layer 530a are removed. In order to create patterns within the superconductor circuit 500D, which can later be used to form via, a reactive ion etching (RIE) method can be utilized. RIE, which is a dry etching technique, can facilitate patterning and etching of the first oxide layer 540b and the first dielectric layer 530a and can involve using a combination of chemically reactive gases and low-pressure plasma to selectively remove portions of the first oxide layer 540b and the first dielectric layer 530a. To that end, the superconductor circuit 500D is placed in a vacuum chamber, where reactive gases are introduced into the chamber. A radiofrequency power source generates a plasma by applying an oscillating electric field to the gas mixture.

The plasma can include ions, electrons, and radicals, which are highly reactive and can chemically interact with the superconductor circuit 500D. Positively charged ions in the plasma accelerate towards the surface of the first oxide layer 540b and the first dielectric layer 530a due to the electric field. These ions impact the surface, physically sputtering away atoms and molecules of the first oxide layer 540b and the first dielectric layer 530a. Reactive radicals in the plasma chemically react with the surface of the first oxide layer 540b and the first dielectric layer 530a, forming volatile byproducts that can be easily removed. In some embodiments, a patterned mask made of a resistant material can be placed on the substrate to protect certain areas from etching. The mask defines the areas where material removal should occur. Due to the directional nature of ion bombardment, RIE can produce anisotropic etching, meaning the etching occurs vertically downwards and minimally laterally. Thus, the RIE can result in well-defined sidewalls and sharp features. In some embodiments, the RIE can be further performed to remove, i.e., etch, the TEOS 540a. The RIE can stop at the surface of the first metal layer 520a.

FIG. 5E illustrates a superconductor circuit 500E after the formation of the second metal layer. In some embodiments, the second metal layer 520b can be deposited over the first metal layer 520a and the first oxide layer 540b.

In some embodiments, prior to forming the second metal layer 520b, the first metal layer 520a is prepared by cleaning and removing any impurities or oxide layers. The second metal layer 520b is deposited onto the first metal layer 520a, using techniques such as CVD or ALD.

In an embodiment, in order to deposit the second metal layer 520b using ALD, the surface of the superconductor circuit 500E is exposed to the first precursor gas, which chemisorbs onto the substrate's surface, forming a monolayer of the desired material. The excess precursor is removed by purging the chamber with an inert gas, ensuring that only the chemisorbed molecules remain on the surface. Subsequently, the superconductor circuit 500E can be exposed to the second precursor gas, which reacts with the chemisorbed layer to form a new layer of the desired material. Again, the excess precursor is purged from the chamber, leaving only the reacted layer behind. The process can be repeated for the desired number of cycles to build up the thin film layer by layer. Alternatively, in some embodiments, in order to deposit the second metal layer 520b using CVD, the precursor gases containing the desired materials are introduced into the deposition chamber and then undergo chemical reactions on the superconductor circuit's surface, leading to the deposition of thin films. This can involve thermal decomposition or reaction with other species on the surface. As the reactions continue, the thin film layer grows in thickness on the surface.

In some embodiments, the second metal layer 520b can be deposited using PVD. PVD can form the second metal layer 520b over the first metal layer 520a and the first oxide 540b through physical processes without involving chemical reactions. To that end, the source material, i.e., the metal, is vaporized through evaporation, sputtering, or arc vaporization. The vaporized metal travels in a vacuum environment to the first metal layer 520a and the first oxide 540b, where it will be deposited. Upon reaching the first metal layer 520a and the first oxide 540b, the vaporized metal condenses and forms a thin film. The film grows by accumulating atoms or molecules on the first metal layer 520a and the first oxide 540b. The deposited atoms or molecules may initially form small clusters or nuclei on the first metal layer 520a and the first oxide 540b. As deposition continues, these nuclei grow and coalesce to form a continuous thin film, i.e., second metal layer 520b. In some embodiments, the PVD-grown MTL 520b ensures high quality of field region interface. In an embodiment, once the PVD is performed, a sidewall sealing step is performed by short-interval in-situ deposition of the metal utilizing either CVD or ALD. Portions of the second metal layer 520b can be patterned, i.e., recessed, which can be used to form a via.

FIG. 5F illustrates a superconductor circuit 500F after depositing the second oxide layer. In some embodiments, once the second metal layer 520b is formed, the second oxide layer 540c is deposited over the second metal layer 520b. In some embodiments, a third dielectric layer 530c is deposited over the recessed portions of the second metal layer 520b and the second oxide layer 540c. A second layer of oxide 540c is then formed over the second dielectric layer 530b. A CMP can be performed after depositing each of the second oxide layer and the third dielectric layer.

FIG. 5G illustrates a superconductor circuit 500G after recessing portions of the second oxide layer and the third dielectric layer. In some embodiments, portions of the second oxide layer 540c and the second dielectric layer 530b, are removed. In order to create patterns within the superconductor circuit 500G, which can later be used to form another via, an RIE method can be utilized to facilitate patterning and etching of the second oxide layer 540c and the second dielectric layer 530b and can involve using a combination of chemically reactive gases and low-pressure plasma to selectively remove portions of the second oxide layer 540c and the second dielectric layer 530b. To that end, the superconductor circuit 500G is placed in a vacuum chamber, where reactive gases are introduced into the chamber. A radiofrequency power source generates a plasma by applying an oscillating electric field to the gas mixture. The plasma can include ions, electrons, and radicals, which are highly reactive and can chemically interact with the superconductor circuit 500G.

Positively charged ions in the plasma accelerate towards the surface of the second oxide layer 540c and the third dielectric layer 530c due to the electric field. These ions impact the surface, physically sputtering away atoms and molecules of the second oxide layer, oxide 540c, and the second dielectric layer 530b. Reactive radicals in the plasma chemically react with the surface of the second oxide 540c and the second dielectric layer 530b, forming volatile byproducts that can be easily removed. In some embodiments, a patterned mask made of a resistant material can be placed on the substrate to protect certain areas from etching. The mask defines the areas where material removal should occur. Due to the directional nature of ion bombardment, RIE can produce anisotropic etching, meaning the etching occurs vertically downwards and minimally laterally. Thus, the RIE can result in well-defined sidewalls and sharp features. In some embodiments, the RIE can be further performed to remove, i.e., etch, the first oxide layer 540b. The RIE can stop at the surface of the second metal layer 520b.

FIG. 5H illustrates a superconductor circuit 500H after the formation of the third metal layer. In some embodiments, the third metal layer 520c can be deposited over the second metal layer 520b and the second oxide layer 540c.

In some embodiments, prior to forming the third metal layer 520c, the second metal layer 520b is prepared by cleaning and removing any impurities or oxide layers. The third metal layer 520c is deposited onto the second metal layer 520b, using techniques such as CVD or ALD.

In an embodiment, in order to deposit the third metal layer 520c using ALD, the surface of the superconductor circuit 500H is exposed to the first precursor gas, which chemisorbs onto the substrate's surface, forming a monolayer of the desired material. The excess precursor is removed by purging the chamber with an inert gas, ensuring that only the chemisorbed molecules remain on the surface. Subsequently, the superconductor circuit 500H can be exposed to the second precursor gas, which reacts with the chemisorbed layer to form a new layer of the desired material. Again, the excess precursor is purged from the chamber, leaving only the reacted layer behind. The process can be repeated for the desired number of cycles to build up the thin film layer by layer. Alternatively, in some embodiments, in order to deposit the third metal layer 520c using CVD, the precursor gases containing the desired materials are introduced into the deposition chamber and then undergo chemical reactions on the superconductor circuit's surface, leading to the deposition of thin films. This can involve thermal decomposition or reaction with other species on the surface. As the reactions continue, the thin film layer grows in thickness on the surface.

In some embodiments, the third metal 520c can be deposited using PVD. PVD can form the third metal layer 520c over the second metal layer 520b and the second oxide 540c through physical processes without involving chemical reactions. To that end, the source material, i.e., the metal, is vaporized through evaporation, sputtering, or arc vaporization. The vaporized metal travels in a vacuum environment to the second metal layer 520b and the second oxide 540c, where it will be deposited. Upon reaching the second metal layer 520b and the second oxide 540c, the vaporized metal condenses and forms a thin film. The film grows by accumulating atoms or molecules on the second metal layer 520b and the second oxide 540c. The deposited atoms or molecules may initially form small clusters or nuclei on the second metal layer 520b and the second oxide 540c. As deposition continues, these nuclei grow and coalesce to form a continuous thin film, i.e., the third metal layer 520c. In some embodiments, the PVD-grown third metal layer 520c ensures high quality of field region interface. In an embodiment, once the PVD is performed, a sidewall sealing step is performed by short-interval in-situ deposition of the metal utilizing either CVD or ALD. Portions of the third metal layer 520c can be patterned, i.e., recessed, which can be used to form another via.

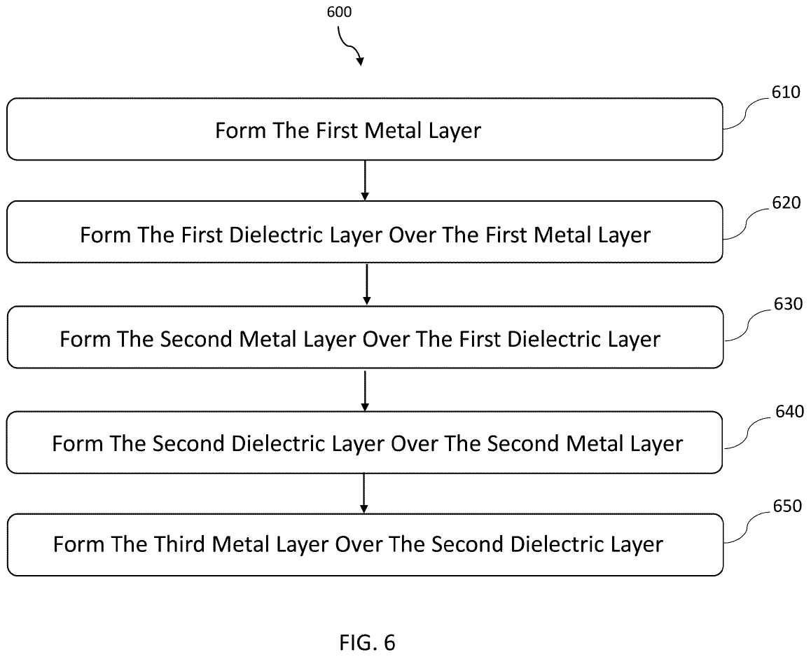

FIG. 6 illustrates block diagrams of method 600 for forming the superconductor circuit in accordance with some embodiments. Method 600 can begin when the first metal layer is formed, as shown by block 610.

In an embodiment, method 600A proceeds when a first dielectric layer over the first metal layer is formed, as shown by block 620.

In some embodiments, method 600 continues when a second metal layer over the first dielectric layer is formed, as shown by block 630.

In some embodiments, method 600 continues when a second dielectric layer over the second metal layer is formed, as shown by block 640.

In some embodiments, method 600 continues when a third metal layer over the second dielectric layer is formed, as shown by block 650. The first and second dielectric layers can include a low-k dielectric material. In some embodiments, the first, second, and third metal layers include the same metal and have a thickness of about 20 nanometers to about 150 nanometers. The first and second dielectric layers can have a thickness of about 40 nanometers to about 300 nanometers. In some embodiments, forming at least one of the first, second, and third metal layers is performed by an ALD or a CVD technique.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing circuits as part of either (a) an intermediate product, such as a motherboard, or (b) an end product. The end product can be any product that includes integrated circuit chips, ranging from low-end applications, such as toys, to advanced computer products having a display, a keyboard or other input circuit, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A superconducting circuit, comprising:
a first metal layer;
a first dielectric layer over the first metal layer;
a second metal layer over the first dielectric layer;
a second dielectric layer over the second metal layer; and
a third metal layer over the second dielectric layer, wherein the first and second dielectric layers include a low-k dielectric material.

2. The superconducting circuit of claim 1, wherein the first, second, and third metal layers include a same metal.

3. The superconducting circuit of claim 1, wherein the first, second, and third metal layers include different metals.

4. The superconducting circuit of claim 1, wherein the first, second, and third metal layers have a thickness of 20 nanometers to 150 nanometers, and wherein the first and second dielectric layers have a thickness of 40 nanometers to 300 nanometers.

5. The superconducting circuit of claim 1, wherein at least one of the first and second dielectric layers includes SiCN.

6. A superconducting circuit, comprising:
a first metal layer;
a first oxide layer over the first metal layer;
a first dielectric layer over the first oxide layer;
a second metal layer over the first oxide layer;
a second oxide layer over the second metal layer;
a second dielectric layer over the second oxide layer; and
a third metal layer over the second dielectric layer.

7. The superconducting circuit of claim 6, wherein the first, second, and third metal layers include different metals.

8. The superconducting circuit of claim 6, wherein the first, second, and third metal layers include a same metal.

9. The superconducting circuit of claim 6, wherein the first, second, and third metal layers have a thickness of 20 nanometers to 150 nanometers.

10. The superconducting circuit of claim 6, wherein the first and second dielectric layers have a thickness of 40 nanometers to 300 nanometers.

11. The superconducting circuit of claim 6, wherein at least one of the first and second dielectric layers includes Silicon carbon nitride (SiCN).

12. The superconducting circuit of claim 6, wherein the first and second dielectric layers include a low-k dielectric material.

13. The superconducting circuit of claim 11, wherein the first and second oxide layers include a same material.

14. The superconducting circuit of claim 13, wherein at least one of the first and second oxide layers includes silicon oxide.

15. A method for forming a superconducting circuit, the method comprising:
forming a first metal layer;
forming a first dielectric layer over the first metal layer;
forming a second metal layer over the first dielectric layer;
forming a second dielectric layer over the second metal layer; and
forming a third metal layer over the second dielectric layer, wherein the first and second dielectric layers include a low-k dielectric material.

16. The method of claim 15, wherein the first, second, and third metal layers include a same metal.

17. The method of claim 15, wherein the first, second, and third metal layers include different metals.

18. The method of claim 15, wherein the first, second, and third metal layers have a thickness of 20 nanometers to 150 nanometers.

19. The method of claim 15, wherein the first and second dielectric layers have a thickness of 40 nanometers to 300 nanometers.

20. The method of claim 15, wherein forming at least one of the first, second, and third metal layers is performed by an atomic layer deposition (ALD) technique or a Chemical Vapor Deposition (CVD) technique.
